(19) United States
(12) Patent Application Publication
(10) Pub. No.: US 2007/0116888 A1
(43) Pub. Date: May 24, 2007

(54) Method and system for performing different deposition processes within a single chamber

(75) Inventor: Jacques Faguet, Albany, NY (US)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/281,343

(22) Filed: Nov. 18, 2005

(51) Int. Cl. C23C 16/00; H05H 1/24; G06F 19/00

(52) U.S. Cl. 427/569; 427/248.1; 700/121; 118/719

(57) ABSTRACT

A method, computer readable medium, and system for vapor deposition on a substrate that introduce a first process gas composition to a process space according to a first vapor deposition process, deposit a first film on the substrate, introduce a second process gas composition into a second process space different in size than the first process space, and deposit a second film on the substrate from the second process gas composition. As such, the system includes a process chamber including a first process space having a first volume. The process chamber further includes a second process space that includes at least a part of the first process space and that has a second volume different from the first volume. The first process space is configured for a first chemical vapor deposition, and the second process space is configured for a second chemical vapor deposition.

### CROSS REFERENCE TO RELATED APPLICATIONS

This application is related to U.S. Ser. No. 11/090,255, Attorney Docket No. 267366US, Client Ref. No. TTCA 19, entitled “A PLASMA ENHANCED ATOMIC LAYER DEPOSITION SYSTEM”, now U.S. Pat. Appl. Publ. No. 2004VVVVVVVVVV, the entire contents of which are incorporated herein by reference. This application is related to U.S. Ser. No. 11/084,176, entitled “A DEPOSITION SYSTEM AND METHOD”, Attorney Docket No. 265595US, Client Ref. No. TTCA 24, now U.S. Pat. Appl. Publ. No. 2004VVVVVVVVVV, the entire contents of which are incorporated herein by reference. This application is related to U.S. Ser. No. ______, entitled “A PLASMA ENHANCED ATOMIC LAYER DEPOSITION SYSTEM HAVING REDUCED CONTAMINATION”, Client Ref. No. TTCA 27, now U.S. Pat. Appl. Publ. No. 2004VVVVVVVVVV, the entire contents of which are incorporated herein by reference. This application is related to U.S. Ser. No. ______, entitled “A DEPOSITION SYSTEM AND METHOD FOR PLASMA ENHANCED ATOMIC LAYER DEPOSITION”, Attorney Docket No. 2274020US, Client Ref. No. TTCA 55, now U.S. Pat. Appl. Publ. No. 2006VVVVVVVVVV, the entire contents of which are incorporated herein by reference.

### BACKGROUND OF THE INVENTION

1. Field of Invention

The present invention relates to a deposition system and a method of operating thereof, and more particularly to a deposition system having multiple process spaces for material deposition.

2. Description of Related Art

Typically, during materials processing, when fabricating composite material structures, plasma is employed to facilitate the addition and removal of material films. For example, in semiconductor processing, a dry plasma etch process is often utilized to remove or etch material along fine lines or within vias or contacts patterned on a silicon substrate. Alternatively, for example, a vapor deposition process is utilized to deposit material along fine lines or within vias or contacts on a silicon substrate. In the latter, vapor deposition processes include chemical vapor deposition (CVD), and plasma enhanced chemical vapor deposition (PECVD).

In PECVD, plasma is utilized to alter or enhance the film deposition mechanism. For instance, plasma excitation generally allows film-forming reactions to proceed at temperatures that are significantly lower than those typically required to produce a similar film by a thermal CVD process that thermally heats the process gas (without plasma excitation) to temperatures near or above the dissociation temperature of the process gas. In addition, plasma excitation may activate film-forming chemical reactions that are not energetically or kinetically favored in thermal CVD. The chemical and physical properties of PECVD films may thus be varied over a relatively wide range by adjusting process parameters.

More recently, atomic layer deposition (ALD) and plasma enhanced ALD (PEALD) have emerged as candidates for ultra-thin gate film formation in front end-of-line (FEOL) operations, as well as ultra-thin barrier layer and seed layer formation for metallization in back end-of-line (BEOL) operations. In ALD, two or more process gases, such as a film precursor and a reduction gas, are introduced alternatingly and sequentially while the substrate is heated in order to form a material film one monolayer at a time. In PEALD, plasma is formed during the introduction of the reduction gas to form a reduction plasma. To date, ALD and PEALD processes have proven to provide improved uniformity in layer thickness and conformality to features on which the layer is deposited, albeit these processes are slower than their CVD and PECVD counterparts.

### SUMMARY OF THE INVENTION

One object of the present invention is directed to addressing various problems with semiconductor processing at ever decreasing line sizes where conformality, adhesion, and purity are becoming increasingly important issues affecting the resultant semiconductor device.

Another object of the present invention is to reduce contamination problems between interfaces of subsequently deposited material layers.

Another object of the present invention is to provide a deposition system capable of changing a process volume size in order to accommodate different deposition processes.

Another object of the present invention is to provide a configuration compatible for vapor deposition and plasma enhanced vapor deposition processes within the same system.

Variations of these and/or other objects of the present invention are provided by certain embodiments of the present invention.

In one embodiment of the present invention, a method is provided for processing a substrate, including disposing a substrate in a vapor deposition system having a process space defined above the substrate, introducing a first process gas composition to the process space according to a first vapor deposition process, depositing a first film on the substrate, introducing a second process gas composition into a second process space different in size from the first process space, and depositing a second film on the substrate from the second process gas composition.

In another embodiment of the present invention, a system for thin film vapor deposition on a substrate is provided that includes a process chamber with a first process space having a first volume. The process chamber further includes a second process space that includes at least a part of the first process space and that has a second volume different from the first volume. The first process space is configured for a first chemical vapor deposition, and the second process space is configured for a second chemical vapor deposition.

### BRIEF DESCRIPTION OF THE DRAWINGS

In the accompanying drawings, a more complete appreciation of the present invention and many attendant advantages thereof will be readily obtained as the same becomes better understood by reference to the following detailed description when considered in connection with the accompanying drawings, wherein:

FIG. 1 depicts a schematic view of a deposition system in accordance with one embodiment of the present invention;

FIG. 2 depicts a schematic view of the deposition system of FIG. 1 showing an enlarged process space in accordance with one embodiment of the present invention;

FIG. 3 depicts a schematic view of a deposition system in accordance with another embodiment of the invention;

FIG. 4 depicts a schematic view of the deposition system of FIG. 3 showing an enlarged process space in accordance with one embodiment of the present invention;

FIG. 5 depicts a schematic timing diagram according to one embodiment of the present invention to be used in the deposition systems of FIGS. 1-4; and

FIG. 6 shows a process flow diagram of a process in accordance with one embodiment of the present invention.

### DETAILED DESCRIPTION OF PREFERRED EMBODIMENTS

In the following description, in order to facilitate a thorough understanding of the invention and for purposes of explanation and not limitation, specific details are set forth, such as a particular geometry of the deposition system and descriptions of various components. However, it should be understood that the invention may be practiced in other embodiments that depart from these specific details.

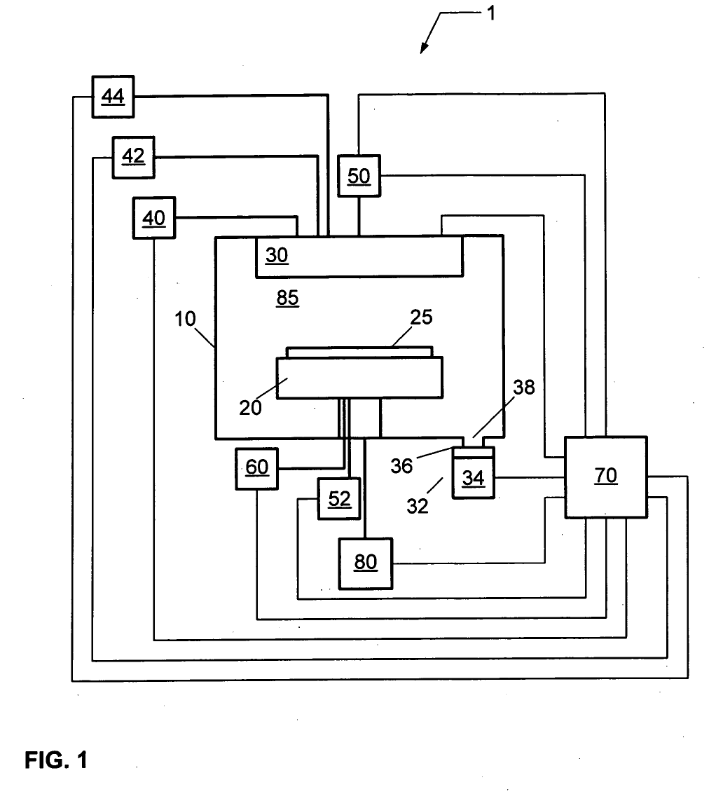

Referring now to the drawings, wherein like reference numerals designate identical or corresponding parts throughout the several views, FIG. 1 illustrates a deposition system 1 for depositing a thin film, for example a barrier film, on a substrate using a vapor deposition process, such as a chemical vapor deposition (CVD) process, a plasma enhanced CVD (PECVD) process, an atomic layer deposition (ALD) process, or a plasma enhanced ALD (PEALD) process. During the metallization of inter-connect and intra-connect structures for semiconductor devices in back-end-of-line (BEOL) operations, a thin conformal barrier layer may be deposited on wiring trenches or vias to minimize the migration of metal into the inter-level or intra-level dielectric, a thin conformal seed layer may be deposited on wiring trenches or vias to provide a film with acceptable adhesion properties for bulk metal fill, and/or a thin conformal adhesion layer may be deposited on wiring trenches or vias to provide a film with acceptable adhesion properties for metal seed deposition. In addition to these processes, a bulk metal such as copper must be deposited within the wiring trench or via.

Oftentimes, for thin conformal films, i.e., barrier layers or seed layers, in back end metallization schemes, it is desirable to use a non-plasma deposition process, such as a thermal vapor deposition process, when depositing the initial thin conformal film over interlevel or intralevel dielectric. Particularly, when this dielectric layer comprises a low dielectric constant (low-k) material, exposure to plasma can cause damage to the low-k layer, that may, for example, affect an increase in the dielectric constant of the film. After using a thermal vapor deposition process to deposit the initial layer, a plasma assisted deposition process may be utilized to improve deposition rate or film morphology or both.

These processes in the past typically could require separate chambers customized to the particular needs of each of these processes as no single chamber could accommodate all of the process requirements. For example, a thin film barrier layer is preferably performed at a self-limited ALD process to provide good conformality. Because ALD requires alternating different process gases, deposition occurs at a relatively slow deposition rate. The present inventors have recognized that performing a thermal ALD process in a small process space volume allows rapid gas injection and an evacuation of the alternating gases, which shortens the ALD cycle. On the other hand, metals, such as tantalum, titanium, tungsten, or copper can be deposited at a faster deposition rate by a thermal CVD process that does not necessarily require alternate gas flows. In this process it may be beneficial to use a larger process space volume to provide more uniform deposition of the material. As another example, described above, depositing one or more layers on a substrate may include a non-plasma process as well as a plasma process. The present inventors have recognized that the non-plasma process can benefit from a small process space volume to increase throughput and/or preserve process gas while a larger process space volume is required to sustain a uniform plasma.

The need for separate chambers adds costs due to the multiplicity of deposition units, adds time to the fabrication process due to the transfer between the systems of the process wafer, and (due to the transfer between multiple deposition units) makes contamination of the exposed interfaces a concern which had to be addressed through preventive or remedial measures, thereby adding more costs and complexity to the fabrication process.

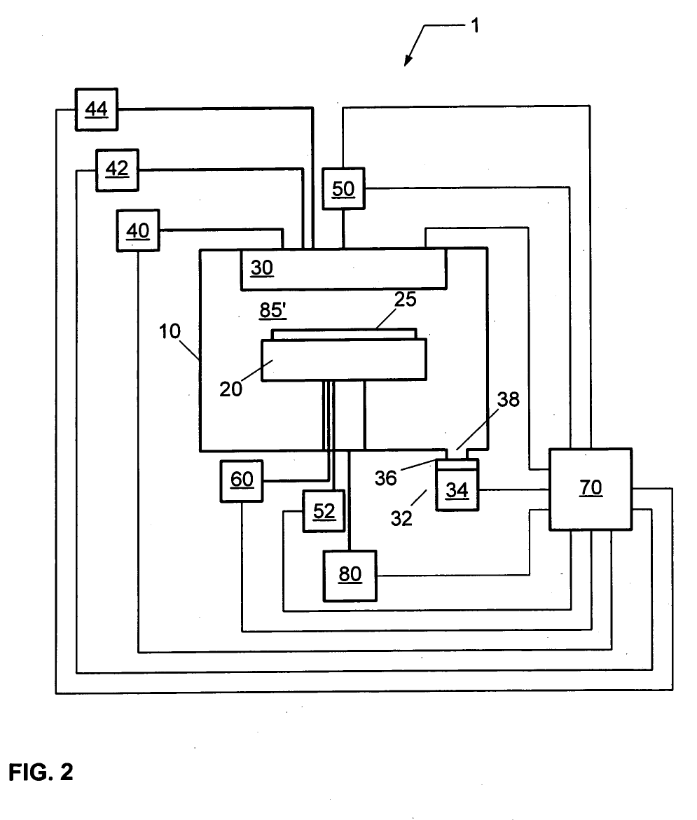

In FIG. 1, deposition system 1 according to one embodiment of the present invention includes a processing chamber 10 having a substrate stage 20 configured to support a substrate 25, upon which a thin film is to be formed. Additionally, the deposition system 1 as illustrated in FIG. 1 includes a process volume adjustment system 80 coupled to the processing chamber 10 and the substrate stage 20, and configured to adjust the volume of the process space adjacent substrate 25. For example, the process volume adjustment system 80 can be configured to vertically translate the substrate stage 20 between a first position creating a first process space 85 with a first volume (see FIG. 1) and a second position creating a second process space 85′ with a second volume (see FIG. 2).

As illustrated in FIGS. 1 and 2, deposition system 1 can include a substrate temperature control system 60 coupled to the substrate stage 20 and configured to elevate and control the temperature of substrate 25. Substrate temperature control system 60 can include temperature control elements, such as a cooling system including a re-circulating coolant flow that receives heat from substrate stage 20 and transfers heat to a heat exchanger system (not shown), or when heating, transfers heat from the heat exchanger system. Additionally, the temperature control elements can include heating/cooling elements, such as resistive heating elements, or thermoelectric heaters/coolers can be included in the substrate stage 20, as well as the chamber wall of the processing chamber 10 and any other component within the deposition system 1.

In order to improve the thermal transfer between substrate 25 and substrate stage 20, substrate stage 20 can include a mechanical clamping system, or an electrical clamping system, such as an electrostatic clamping system, to affix substrate 25 to an upper surface of substrate stage 20. Furthermore, substrate stage 20 can further include a substrate backside gas delivery system configured to introduce gas to the backside of substrate 25 in order to improve the gas-gap thermal conductance between substrate 25 and substrate stage 20. Such a system can be utilized when temperature control of the substrate is required at elevated or reduced temperatures. For example, the substrate backside gas system can include a two-zone gas distribution system, wherein the helium gas gap pressure can be independently varied between the center and the edge of substrate 25.

The substrate stage 20 along with in vacuo mechanisms to translate the substrate stage and interior mechanisms for substrate temperature control system 60 can constitute a lower chamber assembly of the processing chamber 10.

The processing chamber 10 can further include an upper chamber assembly 30 coupled to a first process material gas supply system 40, a second process material gas supply system 42, and a purge gas supply system 44. As such, the upper chamber assembly 30 can provide the first process material and the second process material to process space 85. A showerhead design, as known in the art, can be used to uniformly distribute the first and second process gas materials into the process space 85. Exemplary showerheads are described in greater detail in pending U.S. Patent Application Pub. No. 20040123803, the entire contents of which is incorporated herein by reference in its entirety, and in previously incorporated by reference U.S. Ser. No. 11/090,255.

The deposition system 1 may be configured to process 200 mm substrates, 300 mm substrates, or larger-sized substrates. In fact, it is contemplated that the deposition systems described in the present invention may be configured to process substrates, wafers, or LCDs regardless of their size, as would be appreciated by those skilled in the art. Substrates can be introduced to processing chamber 10, and the substrate may be lifted to and from an upper surface of substrate stage 20 via a substrate lift system (not shown).

According to one embodiment of the present invention, the first process material gas supply system 40 and the second process material gas supply system 42 can be configured to sequentially and optionally alternatingly introduce a first process gas material to processing chamber 10 and a second process gas material to processing chamber 10 in order to sequentially and optionally alternatingly deposit first and second films on substrate 25. The alternation of the introduction of the first process gas material and the introduction of the second process gas material can be cyclical, or it may be acyclical with variable time periods between introduction of the first and second process gas materials. The first and second process gas materials can, for example, include a gaseous film precursor, such as a composition having the principal atomic or molecular species found in the films formed on substrate 25. The gaseous film precursor can originate as a solid phase, a liquid phase, or a gaseous phase, and may be delivered to processing chamber 10 in a gaseous phase. The first and second process gas materials can, for example, include a reduction gas. For instance, the reduction gas can originate as a solid phase, a liquid phase, or a gaseous phase, and may be delivered to processing chamber 10 in a gaseous phase. Examples of gaseous film precursors and reduction gases are given below.

When introducing the first process gas material or the second process gas material to form the first film or the second film, respectively, the gaseous components, i.e., film precursor and reduction gas, of the first process gas material or the second process gas material may be introduced together at the same time to processing chamber 10. For example, the film precursor and the reduction gas may be mixed or they may be un-mixed prior to introduction to processing chamber 10. Alternatively, the gaseous components of the first process gas material or the second process gas material may be sequentially and alternatingly introduced to processing chamber 10. Plasma may or may not be utilized to assist the deposition of the first film and the second film on substrate 25 using the first process gas material and the second process gas material, respectively.

The first material supply system 40, the second material supply system 42, and the purge gas supply system 44 can include one or more material sources, one or more pressure control devices, one or more flow control devices, one or more filters, one or more valves, or one or more flow sensors. The flow control devices can include pneumatic driven valves, electromechanical (solenoidal) valves, and/or high-rate pulsed gas injection valves. An exemplary pulsed gas injection system is described in greater detail in pending U.S. Patent Application Pub. No. 20040123803, the entire contents of which are incorporated herein by reference.

Referring still to FIG. 1, the deposition system 1 in one embodiment of the present invention can include a plasma generation system configured to generate plasma during at least a portion of the sequential and optional alternating introduction of the first process gas material and the second process gas material to processing chamber 10. The plasma generation system can include a first power source 50 coupled to the processing chamber 10, and configured to couple power to the first process gas material, or the second process gas material, or both, or gaseous components of the first process gas material, or gaseous components of the second process gas material. The first power source 50 may include a radio frequency (RF) generator and an impedance match network (not shown), and may further include an electrode (not shown) through which RF power is coupled to plasma in processing chamber 10. The electrode can be formed in the upper assembly 30, and it can be configured to oppose the substrate stage 20.

The impedance match network can be configured to optimize the transfer of RF power from the RF generator to the plasma by matching the output impedance of the match network with the input impedance of the processing chamber, including the electrode, and plasma. For instance, the impedance match network serves to improve the transfer of RF power to plasma in plasma processing chamber 10 by reducing the reflected power. Match network topologies (e.g. L-type, π-type, T-type, etc.) and automatic control methods are well known to those skilled in the art. A typical frequency for the RF power can range from about 0.1 MHz to about 100 MHz. Alternatively, the RF frequency can, for example, range from approximately 400 kHz to approximately 60 MHz, By way of further example, the RF frequency can, for example, be approximately 13.56 or 27.12 MHz.

The deposition system 1 in one embodiment of the present invention can include a substrate bias generation system configured to generate a plasma during at least a portion of the alternating and cyclical introduction of the first process gas material and the second process gas material to processing chamber 10. The substrate bias system can include a second power source 52 coupled to the processing chamber 10, and configured to couple power to substrate 25. The second power source 52 may include a radio frequency (RF) generator and an impedance match network, and may further include an electrode through which RF power is coupled to substrate 25. The electrode can be formed in substrate stage 20. For instance, substrate stage 20 can be electrically biased with a DC voltage or at an RF voltage via the transmission of RF power from an RF generator (not shown) through an impedance match network (not shown) to substrate stage 20. A typical frequency for the RF bias can range from about 0.1 MHz to about 100 MHz. RF bias systems for plasma processing are well known to those skilled in the art. Alternately, RF power can be applied to the substrate stage electrode at multiple frequencies. Alternatively, the RF frequency can, for example, range from approximately 400 kHz to approximately 60 MHz, By way of further example, the RF frequency can, for example, be approximately 13.56 or 27.12 MHz. The substrate bias generation system may operate at a different or the same frequency as the plasma generation system.

Although the plasma generation system and the substrate bias system are illustrated in FIG. 1 as separate entities, these systems may include one or more power sources coupled to substrate stage 20.

Furthermore, the processing chamber 10 is coupled to a pressure control system 32, including for example a vacuum pumping system 34 and a valve 36, through a duct 38. The pressure control system 34 is configured to controllably evacuate the processing chamber 10 to a pressure suitable for forming the thin film on substrate 25, and suitable for use of the first and second process materials.

The vacuum pumping system 34 can include a turbo-molecular vacuum pump (TMP) capable of a pumping speed up to about 5000 liters per second (and greater) and valve 36 can include a gate valve for throttling the chamber pressure. In conventional plasma processing devices utilized for dry plasma etch, a 1000 to 3000 liter per second TMP is generally employed. Moreover, a device for monitoring chamber pressure (not shown) can be coupled to the processing chamber 110. The pressure measuring device can be, for example, a Type 628B Baratron absolute capacitance manometer commercially available from MKS Instruments, Inc. (Andover, Mass.).

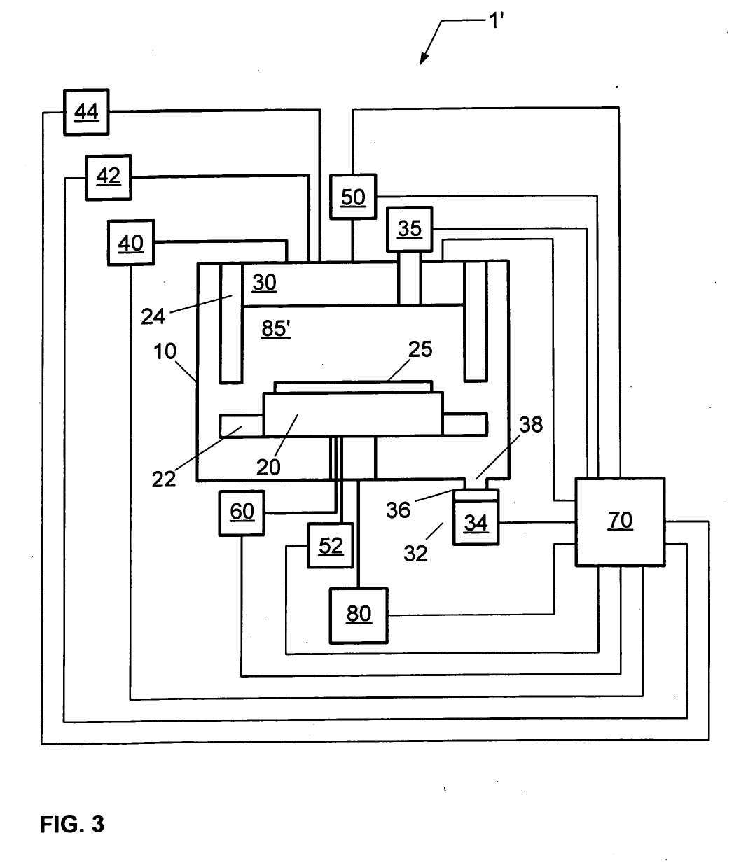

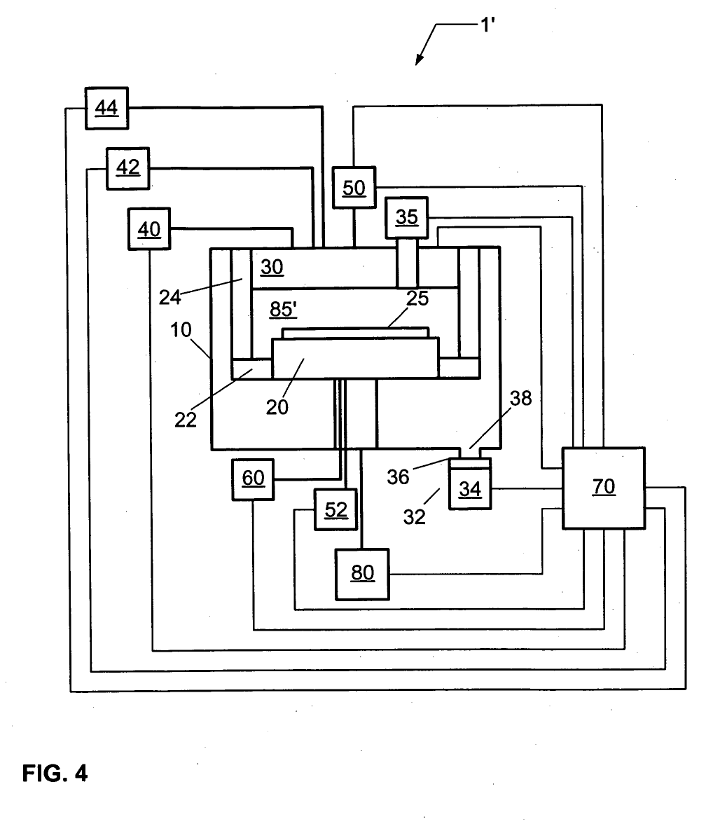

Referring now to FIGS. 3 and 4, a deposition system 1′ is illustrated for depositing a thin film, such as a barrier film, on a substrate using a vapor deposition process, such as a chemical vapor deposition (CVD) process, a plasma enhanced CVD (PECVD) process, an atomic layer deposition (ALD) process, or plasma enhanced ALD (PEALD) process according to another embodiment of the present invention. The deposition system 1′ includes many of the same features as deposition system 1 illustrated in FIGS. 1 and 2, which like reference numerals represent like components. Deposition system 1′ further includes a shield 24 configured to surround a peripheral edge of process space 85 in FIG. 3, or process space 85′ in FIG. 4. Substrate stage 20 may further include an outer lip 22 configured to couple with shield 24 when substrate stage 20 is translated upwards to form process space 85′. For example, outer lip 22 can be configured to seal with shield 24. Shield 24 can be configured to permit passage of process gases there through (as in a perforated shield) in order to permit evacuation of process space 85′. If shield 24 is not configured to permit evacuation of process space 85′, then a separate vacuum pumping system 35 similar to vacuum pumping system 34 can be used to evacuate the process space 85′.

The shield 24 depicted in FIGS. 3 and 4 can serve multiple purposes. The shield 24 can provide a simplified cylindrical geometry in which fluid flow in the process spaces 85 and 85′ can be more reliably predicted or controlled. By having openings at predetermined positions of the shield (i.e., as in a perforated shield) the fluid flow can be engineered. Likewise, the shield 24 can provide a symmetrical path to electrical ground proximate the plasma edge, which can provide a uniform plasma that can be more reliably predicted or controlled. Furthermore, the shield 24 can be a replaceable unit, collecting deposits that would normally accumulate on the interior of walls 10. As such, shield 24 can be replaced in normal routine maintenance and extend the time period before the interior of walls 10 needs to be cleaned.

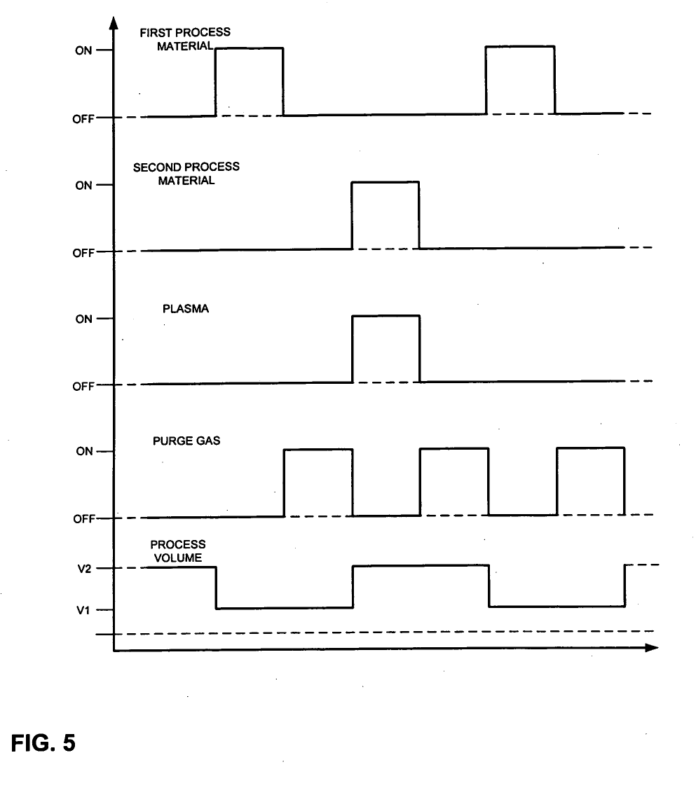

Referring now to FIG. 5, deposition system 1 or 1′ can be configured to perform multiple vapor deposition processes, such as a thermally activated vapor deposition process (i.e., a deposition process not utilizing plasma) followed by a plasma enhanced vapor deposition process (i.e., a deposition process utilizing plasma). The thermally activated vapor deposition process can include a thermal atomic layer deposition (ALD) process or a thermal chemical vapor deposition (CVD) process, and the plasma enhanced vapor deposition process can include a plasma enhanced ALD process or a plasma enhanced CVD process. In one example, when depositing multiple tantalum containing films, a first deposition process such as a thermal ALD or thermal CVD process can be utilized to deposit a first film comprising Ta(C)N, and a second deposition process such as a plasma enhanced ALD process can be utilized to deposit a second film comprising Ta atop the first film.

As illustrated in FIG. 5, when performing the first deposition process, a first process gas material is introduced to the processing chamber, wherein the first process gas material includes a film precursor comprising tantalum, such as a metal halide (e.g., tantalum pentachloride) or a metal organic (e.g., Ta(NC(CH₃)₂C₂H₅)(N(CH₃)₂)₃; hereinafter referred to as TAIMATA®; for additional details, see U.S. Pat. No. 6,593,484) and a reduction gas, The reduction gas can, for instance, include hydrogen or ammonia.

In an ALD process, the introduction of the first process gas material to processing chamber 10 comprises sequentially and alternatingly introducing the film precursor and the reduction gas. Alternatively, in a CVD process, the introduction of the first process gas material to processing chamber 10 comprises concurrent introduction of the film precursor and the reduction gas.

For instance, in thermal ALD, the film precursor is introduced to the processing chamber 10 to cause adsorption of the film precursor to exposed surfaces of substrate 25. Preferably, a monolayer of material adsorbs to the exposed substrate surfaces. Thereafter, the reduction gas is introduced to processing chamber 10 to reduce the adsorbed film precursor in order to leave the desired film on substrate 25. By elevating the substrate temperature, the film precursor thermally decomposes and chemically reacts with the reduction gas. The introduction of the film precursor and the reduction gas are repeated in order to produce a film of a desired thickness. A purge gas may be introduced between introduction of the film precursor and the reduction gas. The purge gas can include an inert gas, such as a noble gas (i.e., helium, neon, argon, xenon, krypton).

Next, as illustrated in FIG. 5, when performing the second deposition process, a second process gas material is introduced to the processing chamber. The second process gas material can be introduced concurrent with or immediately about the time in which the process space is increased in volume from V1 to V2. The second process gas material includes a film precursor comprising tantalum, such as a metal halide (e.g., tantalum pentachloride) or a metal organic (e.g., Ta(NC(CH₃)₂C₂H₅)(N(CH₃)₂)₃; hereinafter referred to as TAIMATA®; for additional details, see U.S. Pat. No. 6,593,484) and a reduction gas. The reduction gas can, for instance, include hydrogen or ammonia.

In a PEALD process, the introduction of the first process gas material to processing chamber 10 comprises sequentially and alternatingly introducing the film precursor and the reduction gas, while coupling power to processing chamber 10 to form plasma during the introduction of the reduction gas. Alternatively, in a PECVD process, the introduction of the first process gas material to processing chamber 10 comprises concurrent introduction of the film precursor and the reduction gas, while coupling power to processing chamber 10 to form plasma.

During plasma formation, power is coupled through, for example, the upper assembly 30 from the first power source 50 to the second process gas material. The coupling of power to the second process gas material heats the second process gas material, thus causing ionization and dissociation of the second process gas material (i.e., plasma formation) in order to form a deposit from the constituents of the second process gas material. As shown in FIG. 5, the processing chamber 10 can be purged with a purge gas for another period of time. The introduction of the first process gas material, the introduction of the second process gas material, and the formation of the plasma while the second process gas material is present can be repeated any number of times to produce a film of desired thickness.

In one example, a thermally-driven vapor deposition process, such as an ALD or CVD process, can be used during the first process described in FIG. 5. As such, tantalum (Ta), tantalum nitride, or tantalum carbonitride can be deposited using a thermally-driven ALD process, in which a Ta carrier such as TaF₅, TaCl₅, TaBr₅, TaI₅, Ta(CO)₅, Ta[N(C₂H₅CH₃)]₅ (PEMAT), Ta[N(CH₃)₂]₅ (PDMAT), Ta[N(C₂H₅)₂]₅ (PDEAT), Ta(NC(CH₃)₃)(N(C₂H₅)₂)₃ (TBTDET), Ta(NC₂H₅)(N(C₂H₅)₂)₃, Ta(NC(CH₃)₂C₂H₅)(N(CH₃)₂)₃, or Ta(NC(CH₃)₃)(N(CH₃)₂)₃, absorbs of the surface of the substrate followed by a exposure to a reduction gas such as H₂, NH₃, N₂ and H₂, N₂H₄, NH(CH₃)₂, or N₂H₃CH₃.

In another example of a thermally-driven vapor deposition process, such as an ALD or CVD process, for the first process shown in FIG. 5, when depositing titanium (Ti), titanium nitride, or titanium carbonitride, the Ti carrier can include TiF₄, TiCl₄, TiBr₄, TiI₄, Ti[N(C₂H₅CH₃)]₄ (TEMAT), Ti[N(CH₃)₂]₄ (TDMAT), or Ti[N(C₂H₅)₂]₄ (TDEAT), and the reduction gas can include H₂, NH₃, N₂ and H₂, N₂H₄, NH(CH₃)₂, or N₂H₃CH₃.

As another example of a thermally-driven vapor deposition process, such as an ALD or CVD process, for the first process shown in FIG. 5, when depositing tungsten (W), tungsten nitride, or tungsten carbonitride, the W carrier can include WF₆, or W(CO)₆, and the reduction gas can include H₂, NH₃, N₂ and H₂, N₂H₄, NH(CH₃)₂, or N₂H₃CH₃.

In another example of a thermally-driven vapor deposition process, such as an ALD or CVD process, for the first process shown in FIG. 5, when depositing molybdenum (Mo), the Mo carrier can include molybdenum hexafluoride (MoF₆), and the reduction gas can include H₂.

When depositing copper in a thermally-driven vapor deposition process, such as an ALD or CVD process, for the first process shown in FIG. 5, the Cu carrier can include Cu-containing organometallic compounds, such as Cu(TMVS)(hfac), also known by the trade name CupraSelect®, available from Schumacher, a unit of Air Products and Chemicals, Inc., 1969 Palomar Oaks Way, Carlsbad, Calif. 92009), or inorganic compounds, such as CuCl. The reduction gas can include at least one of H₂, O₂, N₂, NH₃, or H₂O. As used herein, the term “at least one of A, B, C, . . . or X” refers to any one of the listed elements or any combination of more than one of the listed elements.

In another example of a thermally-driven vapor deposition process, such as an ALD or CVD process, for the first process shown in FIG. 5, when depositing zirconium oxide, the Zr carrier can include Zr(NO₃)₄, or ZrCl₄, and the reduction gas can include H₂O.

When depositing hafnium oxide in a thermally-driven vapor deposition process, such as an ALD or CVD process, for the first process shown in FIG. 5, the Hf carrier can include Hf(OBu^{t})₄, Hf(NO₃)₄, or HfCl₄, and the reduction gas can include H₂O. In another example, when depositing hafnium (Hf), the Hf-carrier can include HfCl₄, and the second process material can include H₂.

In still another example of a thermally-driven vapor deposition process, such as an ALD or CVD process, for the first process shown in FIG. 5, when depositing niobium (Nb), the Nb carrier can include niobium pentachloride (NbCl₅), and the reduction gas can include H₂.

In another example of a thermally-driven vapor deposition process, such as an ALD or CVD process, for the first process shown in FIG. 5, when depositing zinc (Zn), the Zn carrier can include zinc dichloride (ZnCl₂), and the reduction gas can include H₂.

In another example of a thermally-driven vapor deposition process, such as an ALD or CVD process, for the first process shown in FIG. 5, when depositing silicon oxide, the Si-carrier can include Si(OC₂H₅)₄, SiH₂Cl₂, SiCl₄, or Si(NO₃)₄, and the reduction gas can include H₂O or O₂. In another example, when depositing silicon nitride, the Si carrier can include SiCl₄, or SiH₂Cl₂, and the reduction gas can include NH₃, or N₂ and H₂. In another example, when depositing TiN, the Ti carrier can include titanium nitrate (Ti(NO₃)), and the reduction gas can include NH₃.

In another example of a thermally-driven vapor deposition process, such as an ALD or CVD process, for the first process shown in FIG. 5, when depositing aluminum, the Al carrier can include aluminum chloride (Al₂Cl₆), or trimethylaluminum (Al(CH₃)₃), and the reduction gas can include H₂. When depositing aluminum nitride, the Al carrier can include aluminum trichloride, or trimethylaluminum, and the reduction gas can include NH₃, or N₂ and H₂. In another example, when depositing aluminum oxide, the Al carrier can include aluminum chloride, or trimethylaluminum, and the reduction gas can include H₂O, or O₂ and H₂.

In another example of a thermally-driven vapor deposition process, such as an ALD or CVD process, for the first process shown in FIG. 5, when depositing GaN, the Ga carrier can include gallium nitrate (Ga(NO₃)₃), or trimethylgallium (Ga(CH₃)₃), and the reduction gas can include NH₃.

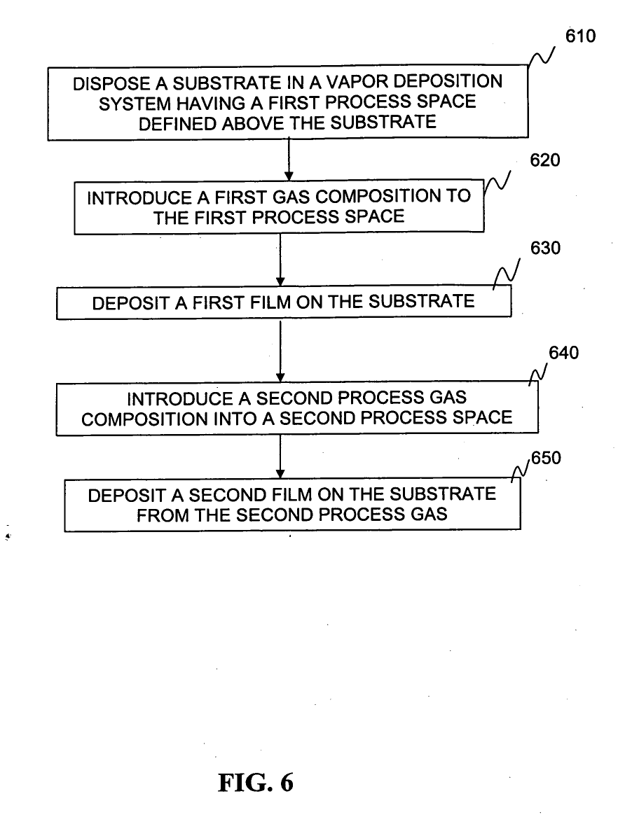

In the examples given above for forming various material layers, the process material deposited for the first process shown in FIG. 6 can include at least one of a metal film, a metal nitride film, a metal carbonitride film, a metal oxide film, or a metal silicate film. Meanwhile, the process material deposited for the second deposition process can include another material film of either the same or different metal composition. For example, the process material deposited for the first process shown in FIG. 6 can include at least one of a tantalum film, a tantalum nitride film, or a tantalum carbonitride film. Meanwhile, the process material deposited for the second deposition process depicted in FIG. 5 can include for example another tantalum film, another tantalum nitride film, or another tantalum carbonitride film (e.g., a tantalum film deposited over a tantalum carbonitride film). Alternatively, for example, the process material deposited for the second deposition process depicted in FIG. 5 can include for example an Al film, or a Cu film deposited for example to metallize a via for connecting for example one metal line to another metal line or for connecting for example a metal line to source/drain contacts of a semiconductor device. The Al or Cu films can be formed with or without a plasma process using precursors for the Al and Cu as described above. Also, the process material deposited for the second deposition process depicted in FIG. 5 can include a zirconium oxide film, a hafnium oxide film, a hafnium silicate film, a silicon oxide film, a silicon nitride film, a titanium nitride film, and/or a GaN film deposited to form an insulating layer such as for example above for a metal line or a gate structure of a semiconductor device.

Further, the first deposition process in FIG. 5 need not occur by an ALD process but could according to the present invention occur using another thermal CVD process using suitable carrier gases known in the art. For example, silane and disilane could be used as silicon carriers for the deposition of silicon-based or silicon-including films. Germane could be used a germanium carrier for the deposition of germanium-based or germanium-including films. Such carriers could likewise be used during the plasma process depicted in FIG. 5. As such, the process material deposited for the first and second deposition process depicted in FIG. 5 can include a metal silicide film and/or a germanium-including film deposited for example to form a conductive gate structure for a semiconductor device.

As illustrated in FIG. 5, following the deposition of the first film, the second film is deposited preferably with a plasma process. A plasma process such as a plasma enhanced chemical vapor deposition (PECVD) process or a plasma enhanced atomic layer deposition process is preferred for the deposition of the second film due to its typically higher growth rate compared to thermal CVD or thermal ALD, respectively. However, other techniques can be used according to the present invention to deposit the second film.

Furthermore, in the above alternating process illustrated in FIG. 5, the process volume can be varied between a first volume (V1) during introduction of the first process gas material for the first time period and optionally the introduction of the purge gas for the second time period, and a second volume (V2) during the introduction of the second process gas material for the third period of time and optionally the introduction of the purge gas for the fourth period of time. An optimal volume for V1 and V2 can be selected for the process space for each process step in the PEALD process.

For example, the first volume (V1) can be sufficiently small such that the first process gas material passes through the process space and some fraction of the first process gas material adsorbs on the surface of the substrate. As the first volume of the process space is reduced, the amount of the first process gas material necessary for adsorption on the substrate surface is reduced and the time required to exchange the first process gas material within the first process space is reduced. For instance, as the first volume of the process space is reduced, the residence time is reduced, hence, permitting a reduction in the first period of time.

Moreover, for example, the second volume (V2) can be set to a volume in which the formation of plasma from the second process material leads to the formation of uniform plasma above the substrate. The ability according to the present invention to be able to provide a plasma process geometry of comparable uniformity to the thermal process geometry permits the present invention to perform consecutive thermal and plasma processes in the same system without the need to transfer the process wafer between different processing systems, thereby saving process time and reducing surface contamination at the interfaces between the process films, leading to improved material properties for the resultant films.

In one embodiment of the present invention, the second volume V2 of the process space defines a process space having an aspect ratio of height to width that is greater than 0.1 and preferably greater than 0.5. For example, as the aspect ratio decreases, the plasma uniformity has been observed to worsen, while as the aspect ratio increases, the plasma uniformity has been observed to improve.

When processing substrates including semiconductor wafers, the process space is substantially cylindrical, characterized by a diameter and a height or spacing between the substrate and the upper assembly. The diameter is related to the size of the substrate, whereas the spacing (or height) can be the variable parameter for adjusting the volume of the process space. The first volume during introduction of the first process material can, for example, include a spacing less than or equal to 20 mm from the substrate stage 20 to the upper assembly 30, and the second volume during introduction of the second process material can, for example, include a spacing greater than 20 mm.

FIG. 6 shows a process flow diagram of a process in accordance with one embodiment of the present invention. The process of FIG. 6 may be performed by the processing system of FIGS. 1-4, or any other suitable processing system. As seen in FIG. 6, in step 610, the process begins when a substrate is disposed in a vapor deposition system having a process space defined above the substrate. In step 620, a first process gas composition is introduced to the process space according to a first vapor deposition process. In step 630, a first film is deposited on the substrate. In step 640, a second process gas composition is introduced into a second process space different in size from the first process space. In step 650, a second film is deposited on the substrate from the second process gas composition.

In steps 630 and 650, the material deposited for the first and second films can be the same material or can be different materials.

In step 610, the vapor deposition system can be configured for at least one of an atomic layer deposition (ALD) process, a plasma enhanced ALD (PEALD) process, a plasma enhanced chemical vapor deposition (PECVD) process, or a thermal chemical vapor deposition (CVD) process. As such, the first film deposited can be deposited with the ALD process, and the second film can be deposited with the PEALD process. Alternatively, the first film deposited can be deposited with the thermal CVD process, and the second film can be deposited with the PECVD process. Alternatively, the first film deposited can be deposited with the ALD process, and the second film can be deposited with the thermal CVD process or the PECVD process.

In step 620, the first process gas composition is introduced in the process space above the substrate surrounded by a shield. In one embodiment of the present invention, the shield can be perforated permitting pumping of the first process gas composition through the shield. If the shield does not have perforations, the interior of the process space can be pumped separately.

In step 650, a substrate stage holding the substrate can be translated to a position that improves the uniformity of deposit of the second film. In step 650, a plasma can be formed by applying RF energy at a frequency from 0.1 to 100 MHz. In one aspect of the present invention, prior to forming the plasma, the volume of the process space is increased in order to facilitate conditions more conducive for plasma uniformity. As such, prior to step 650, the substrate stage can be translated to a position that improves plasma uniformity of the second vapor deposition process. For example, the substrate stage can be set to a position in which the plasma uniformity is better than 2% across a 200 mm diameter of the substrate stage or better than 1% across a 200 mm diameter of the substrate stage.

During step 650, a substrate bias can be provided to the substrate. For example, the substrate bias can be a DC voltage and/or a RF voltage having a frequency from 0.1 to 100 MHz. Prior to step 650, electromagnetic power can be coupled to the vapor deposition system to generate a plasma that accelerates a reduction reaction process at a surface of the first film.

Furthermore, a purge gas can be introduced after depositing the first film. Moreover, with or without the purge gas present, electromagnetic power can be coupled to the vapor deposition system to release contaminants from at least one of the vapor deposition system or the substrate. The electromagnetic power can be coupled into the vapor deposition system in the form of a plasma, an ultraviolet light, or a laser.

In one embodiment of the present invention the purge gas can be a reactive cleaning gas. In this case, the reactive cleaning gas chemically reacts with contaminants on the process chamber walls and/or the substrate surface to assist in removing such impurities from the process chamber. As would be understood by one of ordinary skill in the art, the composition of the reactive gas depends largely on the ALD process and, in particular, the contaminants to be removed from the process chamber. That is, a reactive gas is selected to react with the contaminants to be removed from the process chamber. In considering an example of depositing a tantalum film, using tantalum pentachloride as the first process material and hydrogen for the second process material (i.e., reduction reaction), chlorine contaminants may reside on the processing walls and within the deposited film itself. To remove these chlorine contaminants, ammonia (NH₃) can be introduced to chemically react with the chlorine contaminants and release them from the walls and/or substrate, so that the contaminants can be expelled from the chamber by vacuum pumping.

In another embodiment of the present invention, the process chamber walls may be heated in order to facilitate a chemical reaction to remove the contaminants. For example, when reducing chlorine contaminants as described above, the chamber walls are heated to at least 80° C.

As shown in FIGS. 1-4, deposition systems 1 and 1′ include a controller 70 that can be coupled to processing chamber 10, substrate stage 20, upper assembly 30, first process material supply system 40, second process material supply system 42, purge gas supply system 44, first power source 50, substrate temperature control system 60, and/or process volume adjustment system 80.

The controller 70 can include a microprocessor, memory, and a digital I/O port capable of generating control voltages sufficient to communicate and activate inputs to deposition system 1 (1′) as well as monitor outputs from deposition system 1 (1′) in order to control and monitor the above-discussed processes for film deposition. For example, the controller 70 can include computer readable medium containing program instructions for execution to accomplish the steps described above in relation to FIG. 6. Moreover, the controller 70 may be coupled to and may exchange information with the process chamber 10, substrate stage 20, upper assembly 30, first process material gas supply system 40, second process material supply gas system 42, purge gas supply system 44, first power source 50, second power source 52, substrate temperature controller 60, and/or pressure control system 32. For example, a program stored in the memory may be utilized to activate the inputs to the aforementioned components of the deposition system 1 (1′) according to a process recipe in order to perform one of the above-described non-plasma or plasma enhanced deposition processes.

One example of the controller 70 is a DELL PRECISION WORKSTATION 610™, available from Dell Corporation, Austin, Tex. However, the controller 70 may be implemented as a general-purpose computer system that performs a portion or all of the microprocessor based processing steps of the invention in response to a processor executing one or more sequences of one or more instructions contained in a memory. Such instructions may be read into the controller memory from another computer readable medium, such as a hard disk or a removable media drive. One or more processors in a multi-processing arrangement may also be employed as the controller microprocessor to execute the sequences of instructions contained in main memory. In alternative embodiments, hard-wired circuitry may be used in place of or in combination with software instructions. Thus, embodiments are not limited to any specific combination of hardware circuitry and software.

The controller 70 includes at least one computer readable medium or memory, such as the controller memory, for holding instructions programmed according to the teachings of the invention and for containing data structures, tables, records, or other data that may be necessary to implement the present invention. Examples of computer readable media are compact discs, hard disks, floppy disks, tape, magneto-optical disks, PROMs (EPROM, EEPROM, flash EPROM), DRAM, SRAM, SDRAM, or any other magnetic medium, compact discs (e.g., CD-ROM), or any other optical medium, punch cards, paper tape, or other physical medium with patterns of holes, a carrier wave (described below), or any other medium from which a computer can read.

Stored on any one or on a combination of computer readable media, the present invention includes software for controlling the controller 70, for driving a device or devices for implementing the invention, and/or for enabling the controller to interact with a human user. Such software may include, but is not limited to, device drivers, operating systems, development tools, and applications software. Such computer readable media further includes the computer program product of the present invention for performing all or a portion (if processing is distributed) of the processing performed in implementing the invention.

The computer code devices of the present invention may be any interpretable or executable code mechanism, including but not limited to scripts, interpretable programs, dynamic link libraries (DLLs), Java classes, and complete executable programs. Moreover, parts of the processing of the present invention may be distributed for better performance, reliability, and/or cost.

The term “computer readable medium” as used herein refers to any medium that participates in providing instructions to the processor of the controller 70 for execution. A computer readable medium may take many forms, including but not limited to, non-volatile media, volatile media, and transmission media. Non-volatile media includes, for example, optical, magnetic disks, and magneto-optical disks, such as the hard disk or the removable media drive. Volatile media includes dynamic memory, such as the main memory. Moreover, various forms of computer readable media may be involved in carrying out one or more sequences of one or more instructions to the processor of the controller for execution. For example, the instructions may initially be carried on a magnetic disk of a remote computer. The remote computer can load the instructions for implementing all or a portion of the present invention remotely into a dynamic memory and send the instructions over a network to the controller 70.

The controller 70 may be locally located relative to the deposition system 1 (1′), or it may be remotely located relative to the deposition system 1 (1′). For example, the controller 70 may exchange data with the deposition system 1 (1′) using at least one of a direct connection, an intranet, the Internet and a wireless connection. The controller 70 may be coupled to an intranet at, for example, a customer site (i.e., a device maker, etc.), or it may be coupled to an intranet at, for example, a vendor site (i.e., an equipment manufacturer). Additionally, for example, the controller 70 may be coupled to the Internet. Furthermore, another computer (i.e., controller, server, etc.) may access, for example, the controller 70 to exchange data via at least one of a direct connection, an intranet, and the Internet. As also would be appreciated by those skilled in the art, the controller 70 may exchange data with the deposition system 1 (1′) via a wireless connection.

Although only certain exemplary embodiments of inventions have been described in detail above, those skilled in the art will readily appreciate that many modifications are possible in the exemplary embodiments without materially departing from the novel teachings and advantages of this invention.

1. A method for material deposition on a substrate in a vapor deposition system, comprising:
disposing said substrate in said vapor deposition system having a first process space defined above the substrate;
introducing a first process gas composition to said first process space according to a first vapor deposition process;
depositing a first film on said substrate;
introducing a second process gas composition into a second process space different in size from the first process space; and
depositing a second film on said substrate from the second process gas composition.

2. The method of claim 1, wherein said depositing a second film comprises:
translating a substrate stage to a position that improves uniformity of a deposited second film.

3. The method of claim 2, wherein said depositing comprises:
depositing the second film by plasma enhanced chemical vapor deposition; and
setting the substrate stage to a position in which the plasma uniformity is better than 2% across a 200 mm diameter of the substrate stage.

4. The method of claim 3, wherein said setting comprises:
setting the substrate stage to a position in which the plasma uniformity is better than 1% across a 200 mm diameter of the substrate stage.

5. The method of claim 1, wherein the depositing a first film and the depositing a second film comprise depositing the same material.

6. The method of claim 1, wherein the depositing a first film and the depositing a second film comprise depositing different materials.

7. The method of claim 1, wherein said depositing a first film comprises:
depositing at least one of a tantalum film, a tantalum nitride film, or a tantalum carbonitride film.

8. The method of claim 1, wherein said depositing a second film comprises:
depositing at least one of an Al film, a Cu film, a Zn film, a metal silicide film, or a germanium-including film, or a combination of any one of these films separately or as an alloy.

9. The method of claim 1, wherein:
said depositing a first film comprises depositing a metallization line including at least one of a tantalum film, a tantalum nitride film, a tantalum carbonitride film, an Al film, a Cu film, a Zn film, a metal silicide film, or a germanium-including film, or a combination of any one of these films separately or as an alloy; and
said depositing a second film comprises depositing an interlevel metallization insulation including at least one of a zirconium oxide film, a hafnium oxide film, a silicon oxide film, a silicon nitride film, a titanium nitride, or a GaN film, or a combination of any one of these films.

10. The method of claim 1, wherein said disposing comprises disposing said substrate in a chamber configured to perform at least one of an atomic layer deposition (ALD) process, a plasma enhanced chemical vapor deposition (PECVD) process, or a thermal chemical vapor deposition process.

11. The method of claim 10, wherein:
said depositing a first film comprises depositing the first film using said ALD process; and
said depositing a second film comprises depositing the second film on said substrate using said PECVD process.

12. The method of claim 10, wherein:
said depositing a first film comprises depositing the first film using said thermal CVD process; and
said depositing a second film comprises depositing the second film on said substrate using said PECVD process.

13. The method of claim 10, wherein:
said depositing a first film comprises depositing the first film using said ALD process; and
said depositing a second film comprises depositing the second film on said substrate using said thermal CVD process.

14. The method of claim 1, wherein the introducing a first process gas composition comprises:
introducing the first process gas composition into a region above the substrate surrounded by a shield.

15. The method of claim 14, further comprising:
evacuating said region above the substrate by pumping the first process gas composition through holes in the shield.

16. The method of claim 1, wherein the depositing a second film comprises:
applying RF energy at a frequency from 0.1 to 100 MHz.

17. The method of claim 1, further comprising:
introducing a purge gas after said depositing a first film.

18. The method of claim 1, further comprising:
providing a substrate bias to the substrate at least during deposition of the second film.

19. The method of claim 18, wherein the providing a substrate bias comprises:
biasing the substrate with at least one of a DC voltage or a RF voltage having a frequency from 0.1 to 100 MHz.

20. A computer readable medium containing program instructions for execution on a substrate processing system processor, which when executed by the processor, cause the substrate processing system to perform the any one of the steps recited in claims 1-19.

21. A system for thin film vapor deposition on a substrate, comprising:
a process chamber including,
a first process space having a first volume, and
a second process space that includes at least a part of the first process space and that has a second volume different from the first volume;
said first process space configured for a first chemical vapor deposition; and
said second process space configured for a second chemical vapor deposition.

22. The system of claim 21, further comprising:
a substrate stage configured to hold the substrate during both the first chemical vapor deposition process and the second chemical vapor deposition.

23. The system of claim 22, further comprising:
a first chamber assembly having a gas supply inlet; and
a second chamber assembly supporting the substrate stage and configured to support a vacuum pump configured for evacuation of the process chamber.

24. The system of claim 23, wherein:
said first process space is defined in part by a spacing less than or equal to 20 mm from a topmost part of the substrate stage to a gas inlet surface of the first chamber assembly, and
said second process space is defined in part by a spacing greater than or equal to 20 mm from the topmost part of the substrate stage to the gas inlet surface of the first chamber assembly.

25. The system of claim 22, further comprising:
a process volume adjustment mechanism configured to translate the substrate stage in a direction to change a volume of the first and second process spaces.

26. The system of claim 21, wherein said second process space comprises a space having an aspect ratio of height to width that is greater than 0.1.

27. The system of claim 21, wherein said second process space comprises a space having an aspect ratio of height to width that is greater than 0.5.

28. The system of claim 21, further comprising:
a shield configured to surround a peripheral edge of the first process space.

29. The system of claim 28, wherein the shield comprises a perforated shield.

30. The system of claim 28, further comprising:
a substrate stage configured to hold the substrate during the first chemical vapor deposition and the second chemical vapor deposition; and
said substrate stage having a peripheral lip configured to contact the peripheral edge of the shield.

31. The system of claim 30, wherein said peripheral lip is configured to form a seal to the peripheral edge.

32. The system of claim 31, further comprising:
a vacuum pump configured to evacuate at least the first process space.

33. The system of claim 21, wherein said first process space is configured for at least one of atomic layer deposition (ALD) or thermal chemical vapor deposition (CVD).

34. The system of claim 21, wherein said first process space is configured for deposition of at least one of a tantalum film, a tantalum nitride, or a tantalum carbonitride.

35. The system of claim 21, wherein said second process space is configured for deposition of at least one of an Al film, a Cu film, a Zn film, a metal silicide film, or a germanium-including film, or a combination of any one of these films separately or as an alloy.

36. The system of claim 21, wherein said second process space is configured for deposition of at least one of a zirconium oxide film, a hafnium oxide film, a silicon oxide film, a silicon nitride, a titanium nitride, or a GaN film, or a combination of any one of these films.

37. The system of claim 21, further comprising:
an RF power supply configured to output an RF energy at a frequency from 0.1 to 100 MHz.

38. The system of claim 37, wherein said second process space is configured for plasma enhanced chemical vapor deposition (CVD).

39. The system of claim 37, further comprising:
an electrode connected to the RF power supply and configured to couple said RF energy into at least one of the first and second process space.

40. The system of claim 21, further comprising:
a bias supply configured to output at least one of a DC voltage or an RF voltage at a frequency from 0.1 to 100 MHz.

41. The system of claim 40, further comprising:
an electrode configured to apply a bias said substrate, connected to the RF bias supply and configured to couple said RF voltage onto said substrate.

42. The system of claim 21, further comprising:
a controller configured to control a process in the process chamber.

43. The system of claim 42, wherein the controller is programmed to:
introduce a first process gas composition to said first process space according to a first vapor deposition process;
deposit a first film on said substrate;
translate a position of a substrate stage holding the substrate to form a second process space;
introduce a second process gas composition into the second process space;
deposit a second film on said substrate from said second process composition.
